(19) United States
(12) Patent Application Publication
(10) Pub. No.: US 2022/0181182 A1
(43) Pub. Date: Jun. 9, 2022

(54) SEMICONDUCTOR DEVICE PACKAGE AND METHOD OF MANUFACTURING THE SAME

(71) Applicant: Advanced Semiconductor Engineering, Inc., Kaohsiung (TW)

(72) Inventors: Jenchun CHEN, Kaohsiung (TW); Kuo Kai HUANG, Kaohsiung (TW)

(73) Assignee: Advanced Semiconductor Engineering, Inc., Kaohsiung (TW)

(21) Appl. No.: 17/111,328

(22) Filed: Dec. 3, 2020

(51) Int. Cl. H01L 21/683; H01L 21/673

(52) U.S. Cl. CPC H01L 21/683; H01L 21/673

(57) ABSTRACT

The present disclosure relates to an electronic component. The electronic component includes a first surface, a first functional region, and a non-functional region. The first functional region is disposed on the first surface of the electronic component. The non-functional region is recessed from the first surface of the electronic component.

### BACKGROUND

### 1. Technical Field

The present disclosure relates to a semiconductor device package, and more particularly to a semiconductor device package including a suction hole.

### 2. Description of the Related Art

In semiconductor device packages, one or more electronic components may be disposed on a substrate and electrically connected to the substrate by a pick-and-place machine. In general, suction devices (e.g., nozzles) are commonly used to pick up the electronic components and to place them on the substrate. However, as the size of the electronic components decreases, the suction area of said electronic components will be reduced as well. Insufficient suction area reduces the suction force between the electronic components and the suction devices, which in turn reduces the speed of the pick-and-place operation.

### SUMMARY

In accordance with some embodiments of the present disclosure, an electronic component includes a first surface, a first functional region, and a non-functional region. The first functional region is disposed on the first surface of the electronic component. The non-functional region is recessed from the first surface of the electronic component.

In accordance with some embodiments of the present disclosure, an electronic component includes a first surface and a hole. The first surface has a restriction area and a first signal terminal within the first restriction area. The hole is recessed from the first surface of the electronic component and outside the restriction area.

In accordance with some embodiments of the present disclosure, a method for manufacturing a semiconductor device includes (a) providing an electronic component having a first surface, the electronic component having a first hole extending from the first surface into the electronic component; and (b) applying a suction force on a sidewall and a bottom surface of the first hole.

### BRIEF DESCRIPTION OF THE DRAWINGS

FIG. 1A illustrates a cross-sectional view of a semiconductor device package, in accordance with some embodiments of the present disclosure.

FIG. 1B illustrates a top view of an electronic component, in accordance with some embodiments of the present disclosure.

FIG. 1C illustrates an enlarged view of the electronic component as shown in FIG. 1B, in accordance with some embodiments of the present disclosure.

FIG. 1D illustrates a cross-sectional view of a hole of the electronic component as shown in FIG. 1C, in accordance with some embodiments of the present disclosure.

FIG. 2A, FIG. 2B, FIG. 2B′, FIG. 2B″, and FIG. 2C illustrate a semiconductor manufacturing method in accordance with some embodiments of the present disclosure.

Common reference numerals are used throughout the drawings and the detailed description to indicate the same or similar components. The present disclosure will be readily understood from the following detailed description taken in conjunction with the accompanying drawings.

### DETAILED DESCRIPTION

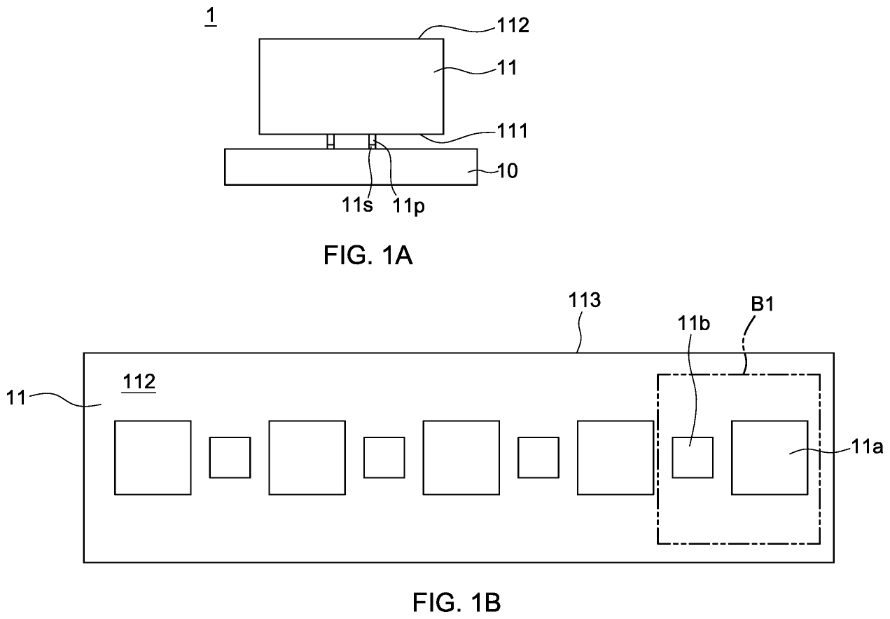

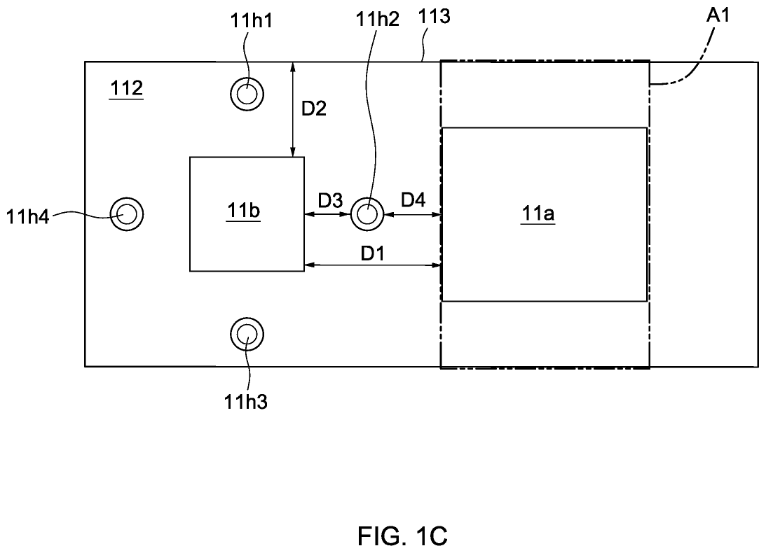

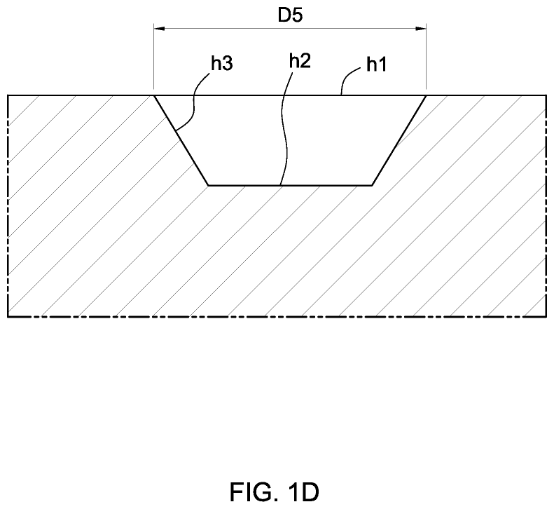

FIG. 1A illustrates a cross-sectional view of a semiconductor device package 1, in accordance with some embodiments of the present disclosure. The semiconductor device package 1 includes a substrate 10 and an electronic component 11.

The substrate 10 may be, for example, a printed circuit board, such as a paper-based copper foil laminate, a composite copper foil laminate, or a polymer-impregnated glass-fiber-based copper foil laminate. The substrate 10 may include an interconnection structure, such as a redistribution layer (RDL) or a grounding element. In some embodiments, the substrate 10 may be a single-layer substrate or multi-layer substrate.

The electronic component 11 is disposed on the substrate 10. The electronic component 11 has an active surface 111 facing the substrate 10 and a backside surface 112 opposite to the active surface 111. The electronic component 11 is electrically connected to the substrate 10. For example, the electronic component 11 may include one or more electrical contacts 11p (e.g., conductive pillars or conductive bumps) on its active surface 111, and the electrical contacts 11p are electrically connected to the substrate 10 via solders 11s (e.g., soldering material such as solder pastes or solder balls). In some embodiments, the electronic component 11 may include a substrate (e.g., a printed circuit board, such as a paper-based copper foil laminate, a composite copper foil laminate, or a polymer-impregnated glass-fiber-based copper foil laminate), an active device (e.g., a die or a chip), a passive device (e.g., a capacitor, a resistor or an inductor) or the like.

In some embodiments, as shown in FIG. 1B, which illustrates a top view of the electronic component 11, the electronic component 11 may include one or more conductive layers 11a, 11b on its backside surface 112. In some embodiments, the conductive layers 11a, 11b may include terminals, conductive pads, antennas (e.g., patch antennas) or any elements having emitting and receiving functions. In some embodiments, the conductive layers 11a, 11b can be referred to as functional regions of the backside surface 112 of the electronic component 11, which can be configured to transmit or receive signals. In some embodiments, the conductive layers 11a, 11b may be top surfaces of conductive pillars that penetrate the electronic component 11. For example, the conductive layers 11a, 11b may be the top surfaces of the conductive pillars exposed from the backside surface 112.

In some embodiments, an area of the conductive layer 11a is larger than an area of the conductive layer 11b. For example, a length of the conductive layer 11a is larger than a length of the conductive layer 11b. For example, a width of the conductive layer 11a is larger than a width of the conductive layer 11b. In some embodiments, a distance between the conductive layer 11a and an edge 113 of the backside surface 112 of the electronic component 11 is less than a distance between the conductive layer 11b and the edge 113 of the backside surface 112 of the electronic component 11. For example the conductive layer 11a is closer to the edge 113 of the backside surface 112 of the electronic component 11 than the conductive layer 11b.

FIG. 1C illustrates an enlarged view of a portion of the electronic component 11 encircled by a dotted-line box B1 as shown in FIG. 1B, in accordance with some embodiments of the present disclosure. As shown in FIG. 1C, one or more holes 11h1, 11h2, 11h3, and 11h4 are located on the backside surface 112 of the electronic component 11. The holes 11h1, 11h2, 11h3, and 11h4 may surround the conductive layer 11b. For example, the holes 11h1, 11h2, 11h3, and 11h4 are located adjacent to edges of the conductive layer 11b. The holes 11h1, 11h2, 11h3, and 11h4 may partially extend from the backside surface 112 toward the active surface 111 of the electronic component 11 without fully penetrating the electronic component 11. For example, a depth of each of the holes 11h1, 11h2, 11h3, and 11h4 is less than a thickness of the electronic component 11. In some embodiments, the holes 11h1, 11h2, 11h3, and 11h4 can be referred to as non-functional regions, which cannot be configured to transmit or receive signals. In some embodiments, the holes 11h1, 11h2, 11h3, and 11h4 include blind holes.

In some embodiments, there may be any number of holes located adjacent to the conductive layer 11b. For example, there are N holes located adjacent to the conductive layer 11b, where N is an integer equal to or greater than 1. In some embodiments, the shape of the holes 11h1, 11h2, 11h3, and 11h4 can be adjusted depending on design requirements. For example, the holes 11h1, 11h2, 11h3, and 11h4 may be circular, rectangular, triangular, polygonal, or irregular. In some embodiments, the holes 11h1, 11h2, 11h3, and 11h4 may be replaced by one or more trenches. The trenches may extend along the edges of the conductive layer 11b. The trenches may fully surround the edges of the conductive layer 11b. In some embodiments, the holes 11h1, 11h2, 11h3, and 11h4 and the electronic component 11 are integratedly formed. In some embodiments, the electronic component 11 can be formed, and then the holes 11h1, 11h2, 11h3, and 11h4 may be formed by mechanical drilling, laser drilling, or etching.

In some embodiments, a region A1 (which may be referred to as a restriction region) of the backside surface 112 of the electronic component 11 on which the conductive layer 11a is disposed is free from holes. For example, the holes 11h1, 11h2, 11h3, and 11h4 are not located within the region A1.

In some embodiments, a distance D1 between the conductive layer 11b and the conductive layer 11a (or the region A1) is about 1.5 millimeters (mm). In some embodiments, a distance D2 between an edge of the conductive layer 11b and an edge of the backside surface 112 of the electronic component 11 is about 0.7 mm. In some embodiments, a distance D3 between the hole 11h2 (which is located between the conductive layer 11a and the conductive layer 11b) and the conductive layer 11b is equal to or less than a distance D4 between the hole 11h2 and the conductive layer 11a. For example, the hole 11h2 may be closer to the conductive layer 11b than the conductive layer 11a. In some embodiments, the distance D3 or D4 is about 0.1 mm.

FIG. 1D illustrates a cross-sectional view of one of the holes 11h1, 11h2, 11h3, and 11h4, in accordance with some embodiments of the present disclosure. As shown in FIG. 1D, the holes 11h1, 11h2, 11h3, and 11h4 may be tapered from their opening h1 toward their bottom surface h2. For example, a width (or diameter) D5 of the opening h1 of each of the holes 11h1, 11h2, 11h3, and 11h4 is greater than a width (or diameter) of the bottom surface h2 of each of the holes 11h1, 11h2, 11h3, and 11h4. A lateral surface (or sidewall) h3 of each of the holes 11h1, 11h2, 11h3, and 11h4 is inclined. For example the lateral surface h3 and the bottom surface h2 define an angle greater than 90 degrees. In some embodiments, the width D5 of the opening h1 of the holes 11h1, 11h2, 11h3, and 11h4 is in a range from 0.4 mm to 1.2 mm. In some embodiments, the openings h1 of the holes 11h1, 11h2, 11h3, and 11h4 may include the same width. Alternatively, the openings h1 of the holes 11h1, 11h2, 11h3, and 11h4 may include different widths. For example, the openings of the holes 11h1 and 11h3 may be larger than those of the holes 11h2 and 11h4. In some embodiments, the holes 11h1, 11h2, 11h3, and 11h4 may include the same depth. Alternatively, the holes 11h1, 11h2, 11h3, and 11h4 may include different depths.

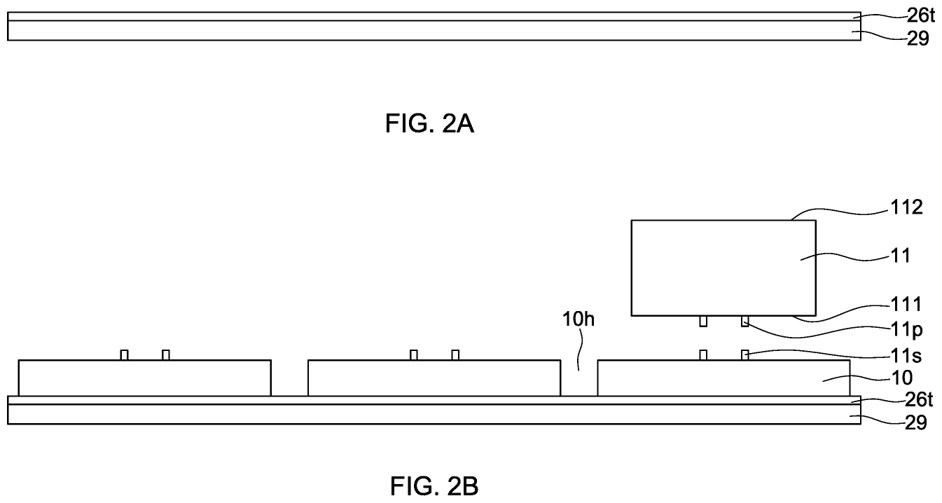

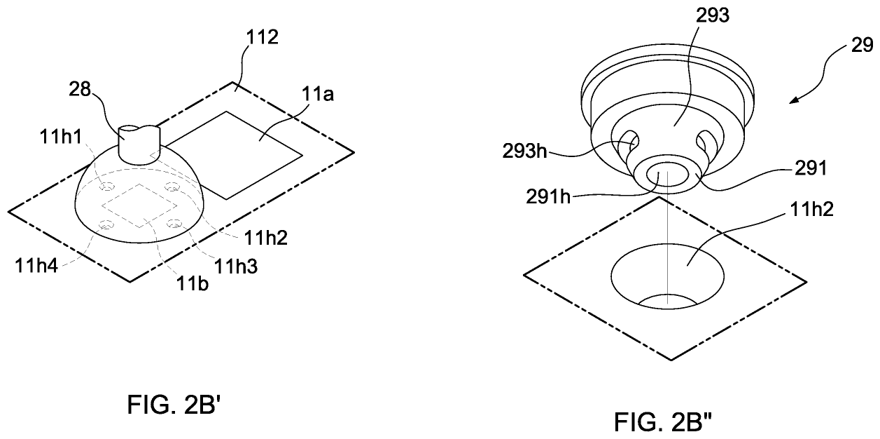

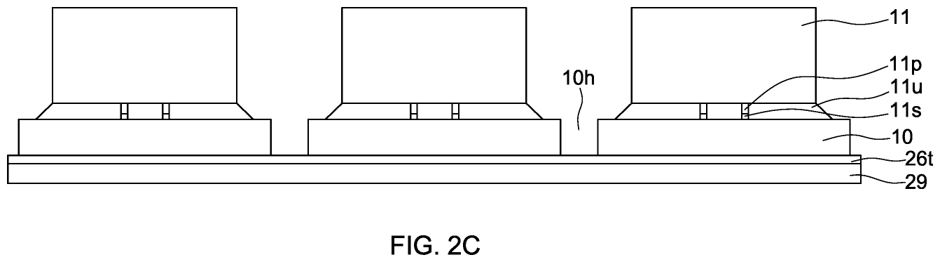

FIG. 2A, FIG. 2B, FIG. 2B′, FIG. 2B″, and FIG. 2C illustrate a semiconductor manufacturing method, in accordance with some embodiments of the present disclosure.

Referring to FIG. 2A, a carrier 29 is provided. In some embodiments, the carrier 29 has an adhesive layer 26t (e.g., a tape, a glue, an adhesive film or the like) disposed thereon. In some embodiments, a baking operation may be carried out.

Referring to FIG. 2B, a plurality of substrates including a substrate 10 is disposed on the carrier 29. The substrates are connected to the carrier 29 through the adhesive layer 26t. In some embodiments, the substrates are disposed on the carrier 29 by, for example, pick-and-place or any other suitable techniques. The substrates are separated from each other. For example, there is a gap 10h (or a distance) between two adjacent substrates 10. One or more solders 11s (or solder paste) are formed on each of the substrates. In some embodiments, the solders 11s may be formed by, for example, printing or any other suitable operations.

Electronic components 11 are disposed on each of the substrates including the substrate 10. The electronic components 11 are electrically connected to the corresponding substrates through electrical contact 11p and the solders 11s. In some embodiments, the electronic components 11 are disposed on the substrates by, for example, pick-and-place or any other suitable techniques. The electronic component 11 is the same or similar to the electronic component 11 as shown in FIG. 1A.

FIG. 2B′ illustrates an enlarged view of a portion of the electronic component 11 during the pick-and-place operation, in accordance with some embodiments of the present disclosure. As shown in FIG. 23, a suction device 28 (e.g., a nozzle) covers a portion (e.g., a suction area) of a backside surface 112 of the electronic component 11. The suction device 28 covers holes 11h1, 11h2, 11h3, 11h4, and the conductive layer 11b. The suction device 28 does not cover the conductive layer 11a (e.g., the region A1 as shown in FIG. 1C). For example, the suction device 28 is spaced apart from the region A1 as shown in FIG. 1C. In other embodiments, the suction device 28 may cover the region A1 as shown in FIG. 1C. However, the conductive layer 11a should be prevented from being contacted by the suction device, and thus the rest area in the region A1 may be insufficient for the suction device 28 to pick up the electronic component 11. Therefore, it is preferable to place the suction device 28 to cover the regions outside the region A1 (e.g., cover the regions surrounding the conductive layer 11b).

In operation, the suction device 28 is configured to provide a suction force to the electronic component 11 to pick up the electronic component by exhaling air from the space covered by the suction device 28. For example, the suction force can be applied to the portion of the backside surface 112 covered by the suction device 28, and the bottom surface and the lateral surface (e.g., the bottom surface h2 and the lateral surface h3 as shown in FIG. 1D) of each of the holes 11h1, 11h2, 11h3, 11h4. After the electronic component 11 is moved to the predetermined location of the corresponding substrate 10, the suction device 28 stops providing the suction force and is removed from the electronic component 11.

In some embodiments, the holes 11h1, 11h2, 11h3, 11h4 can be omitted, and the suction force is merely applied to the portion of the backside surface 112 of the electronic component 11. However, as the size of the electronic component 11 decreases, the suction area of said electronic component 11 will be reduced as well. Since the suction force is determined based on the total suction area, insufficient suction area reduces the suction force between the electronic component 11 and the suction device 28, which in turn reduces the speed of the pick-and-place operation.

In accordance with the embodiments of the present disclosure, additional suction areas can be increased by forming one or more holes 11h1, 11h2, 11h3, 11h4 on the backside surface 112 of the electronic component 11. For example, the additional suction areas may include the lateral surface and the bottom surface of each of the holes 11h1, 11h2, 11h3, 11h4. Hence, the suction force between the electronic component 11 and the suction device 28 can be enhanced, which in turn enhances the speed of the pick-and-place operation. For example, the pick-up-place operation for the electronic component 11 as shown in FIGS. 1B, 1C, and 1D is 6 times faster than that for an electronic component without any hole on its backside surface.

FIG. 2B″ illustrates an enlarged view of a portion of the electronic component 11 during the pick-and-place operation, in accordance with some embodiments of the present disclosure. A suction device 29 is similar to the suction device 28 as shown in FIG. 2B′, and one of the differences therebetween is that the suction device 28 covers the conductive layer 11b and all the holes 11h1, 11h2, 11h3, and 11h4 while the suction device 29 is disposed within each of the holes 11h1, 11h2, 11h3, and 11h4.

In some embodiments, the suction device 29 is substantially conformal to the profile (or outline) of each of the holes 11h1, 11h2, 11h3, and 11h4. For example, the suction device 29 has a tapered shape. The suction device 29 has a lateral surface 293 corresponding to the lateral surface of each of the holes 11h1, 11h2, 11h3, and 11h4. The suction device 29 has a bottom surface 291 corresponding to the bottom surface of each of the holes 11h1, 11h2, 11h3, and 11h4. The bottom surface 291 has one or more openings 291h to provide a suction force on the bottom surface of each of the holes 11h1, 11h2, 11h3, and 11h4. The lateral surface 293 has one or more openings 293h to provide a suction force on the lateral surface of each of the holes 11h1, 11h2, 11h3, and 11h4.

In operation, the suction device 29 is configured to provide a suction force to the electronic component 11 to pick up the electronic component by exhaling air from the space covered by the suction device 28. For example, the suction force can be applied to the bottom surface and the lateral surface (e.g., the bottom surface h2 and the lateral surface h3 as shown in FIG. 1D) of each of the holes 11h1, 11h2, 11h3, 11h4. After the electronic component 11 is moved to the predetermined location of the corresponding substrate 10, the suction device 29 stops providing the suction force and is removed from the electronic component 11.

Referring to FIG. 2C, an underfill 11u may be formed between the electronic component 11 and the substrate 10 to cover or encapsulate the electrical contacts 11p and the solders 11s. In some embodiments, the underfill 11u includes an epoxy resin, a molding compound (e.g., an epoxy molding compound or other molding compound), a polyimide, a phenolic compound or material, a material including a silicone dispersed therein, or a combination thereof.

Then, the semiconductor device packages are detached from the carrier 29 and the adhesive layer 26t to form individual semiconductor device packages. In other embodiments, each of the semiconductor device packages is picked up from the adhesive layer 26t.

As used herein, the terms “substantially,” “substantial,” “approximately,” and “about” are used to denote and account for small variations. For example, when used in conjunction with a numerical value, the terms can refer to a range of variation of less than or equal to ±10% of that numerical value, such as less than or equal to ±5%, less than or equal to ±4%, less than or equal to ±3%, less than or equal to ±2%, less than or equal to ±1%, less than or equal to ±0.5%, less than or equal to ±0.1%, or less than or equal to ±0.05%. As another example, a thickness of a film or a layer being “substantially uniform” can refer to a standard deviation of less than or equal to ±10% of an average thickness of the film or the layer, such as less than or equal to ±5%, less than or equal to ±4%, less than or equal to ±3%, less than or equal to ±2%, less than or equal to ±1%, less than or equal to ±0.5%, less than or equal to ±0.1%, or less than or equal to ±0.05%. The term “substantially coplanar” can refer to two surfaces within micrometers of lying along a same plane, such as within 40 within 30 within 20 within 10 or within 1 μm of lying along the same plane. Two surfaces or components can be deemed to be “substantially perpendicular” if an angle therebetween is, for example, 90°±10°, such as ±5°, ±4°, ±3°, ±2°, ±1°, ±0.5°, ±0.1°, or ±0.05°. When used in conjunction with an event or circumstance, the terms “substantially,” “substantial,” “approximately,” and “about” can refer to instances in which the event or circumstance occurs precisely, as well as instances in which the event or circumstance occurs to a close approximation.

As used herein, the singular terms “a,” “an,” and “the” may include plural referents unless the context clearly dictates otherwise. In the description of some embodiments, a component provided “on” or “over” another component can encompass cases where the former component is directly on (e.g., in physical contact with) the latter component, as well as cases where one or more intervening components are located between the former component and the latter component.

As used herein, the terms “conductive,” “electrically conductive” and “electrical conductivity” refer to an ability to transport an electric current. Electrically conductive materials typically indicate those materials that exhibit little or no opposition to the flow of an electric current. One measure of electrical conductivity is Siemens per meter (S/m). Typically, an electrically conductive material is one having a conductivity greater than approximately 10⁴ S/m, such as at least 10⁵ S/m or at least 10⁶ S/m. The electrical conductivity of a material can sometimes vary with temperature. Unless otherwise specified, the electrical conductivity of a material is measured at room temperature.

Additionally, amounts, ratios, and other numerical values are sometimes presented herein in a range format. It can be understood that such range formats are used for convenience and brevity, and should be understood flexibly to include not only numerical values explicitly specified as limits of a range, but also all individual numerical values or sub-ranges encompassed within that range as if each numerical value and sub-range is explicitly specified.

While the present disclosure has been described and illustrated with reference to specific embodiments thereof, these descriptions and illustrations do not limit the present disclosure. It can be clearly understood by those skilled in the art that various changes may be made, and equivalent elements may be substituted within the embodiments without departing from the true spirit and scope of the present disclosure as defined by the appended claims. The illustrations may not necessarily be drawn to scale. There may be distinctions between the artistic renditions in the present disclosure and the actual apparatus, due to variables in manufacturing processes and such. There may be other embodiments of the present disclosure which are not specifically illustrated. The specification and drawings are to be regarded as illustrative rather than restrictive. Modifications may be made to adapt a particular situation, material, composition of matter, method, or process to the objective, spirit and scope of the present disclosure. All such modifications are intended to be within the scope of the claims appended hereto. While the methods disclosed herein have been described with reference to particular operations performed in a particular order, it can be understood that these operations may be combined, sub-divided, or re-ordered to form an equivalent method without departing from the teachings of the present disclosure. Therefore, unless specifically indicated herein, the order and grouping of the operations are not limitations of the present disclosure.

What is claimed is:

1. An electronic component, comprising:
a first surface;
a first functional region disposed on the first surface of the electronic component; and
a non-functional region recessed from the first surface of the electronic component.

2. The electronic component of claim 1, further comprising a second functional region disposed on the first surface of the electronic component, wherein the non-functional is disposed between the first functional region and the second functional region.

3. The electronic component of claim 2, wherein an area of the second functional region is larger than an area of the first functional region.

4. The electronic component of claim 2, wherein a distance between the first functional region and the non-functional region is larger than a distance between the second functional region and the non-functional region.

5. The electronic component of claim 1, wherein the non-functional region includes a hole exposing an inner lateral surface of the electronic component.

6. The electronic component of claim 5, further comprising a plurality of holes surrounding the first functional region.

7. The electronic component of claim 5, wherein the hole is tapered from the first surface of the electronic component into the electronic component.

8. The electronic component of claim 1, wherein the non-functional region is configured for a suction area.

9. An electronic component, comprising:
a first surface having a restriction area and a first signal terminal within the first restriction area; and
a hole recessed from the first surface of the electronic component and outside the restriction area.

10. The electronic component of claim 9, further comprising a second signal terminal outside the restriction area and outside the hole.

11. The electronic component of claim 10, further comprising a plurality of restriction areas and second signal terminals, wherein the restriction areas and the second signal terminals are alternatingly arranged.

12. The electronic component of claim 11, further comprising a plurality of holes surrounding the second signal terminal.

13. The electronic component of claim 10, wherein an area of the first signal terminal is larger than an area of the second signal terminal.

14. The electronic component of claim 10, wherein
the first signal terminal and the second signal terminal are arranged in a first direction; and
a distance between the second signal terminal and an edge of the first surface of the electronic component extending along the first direction is larger than a distance between the first signal terminal and the edge of the first surface of the electronic component.

15. The electronic component of claim 10, wherein a distance between the first signal terminal and the hole is larger than a distance between the second signal terminal and the hole.

16. The electronic component of claim 9, wherein the hole includes a blind hole.

17. A method for manufacturing a semiconductor device, comprising:
(a) providing an electronic component having a first surface, the electronic component having a hole extending from the first surface into the electronic component; and
(b) applying a suction force on a sidewall and a bottom surface of the hole.

18. The method of claim 17, further comprising providing the suction force on a portion of the first surface and a terminal on the first surface.

19. The method of claim 17, further comprising providing a suction device into the hole.

20. The method of claim 17, in step (b) further comprising sucking electronic component.
